(19) United States
(12) Patent Application Publication
(10) Pub. No.: US 2007/0008023 A1
(43) Pub. Date: Jan. 11, 2007

(54) Differential-type delay cell circuit

(76) Inventor: Jinn-Shyan Wang, Chiayi City (TW)

Correspondence Address: RABIN & Berdo, PC, 1101 14TH STREET, NW, SUITE 500, WASHINGTON, DC, 20005, US

(21) Appl. No.: 11/175,163

(22) Filed: Jul. 7, 2005

(51) Int. Cl. H03H 11/26

(52) U.S. Cl. 327/276

(57) ABSTRACT

A differential-type delay cell is disclosed herein. The delay cell provides two signal paths, each of which has a capacitor connected to the ground. The capacitance difference between the two capacitors determines the finest delay resolution of the delay cell. The delay cell does not rely on logic gates to increase driving capability. Additionally, unlike conventional approaches that implement multiplexing at the output end, the delay cell has de-multiplexing at the input end so that the components along one single signal path will be activated at any point of time.

### BACKGROUND OF THE INVENTION

1. Field of the Invention

The present invention generally relates to delay cells, and more particularly to a differential-type delay cell for composing delay locked loops.

2. The Prior Arts

As the computational and transmission speeds continue to rise in an exponential rate, integrated circuits have decreasing tolerance towards clock jitters and phase errors. Delay locked loops, characterized in their synchronized input and output clocks, have therefore been widely applied in the clock generators of these integrated circuits requiring low jitter and high phase precision. A conventional way of building a delay locked loop is by connecting a number of delay cells in serial stages. In this approach, therefore, the design of each delay cell has a direct impact on the entire delay locked loop, as their power consumption and clock jitter are totaled to become that of the delay locked loop.

FIG. 1a is a schematic diagram showing a conventional delay cell. As illustrated, the delay cell provides two signal paths, marked as “path 1” and “path 2” in the diagram, between the input and output terminals CK_i and CK_o. Path 2 has a capacitor C connected to the ground, which is realized by a transistor whose size could be tuned during the manufacturing process. The capacitor C is charged by the input signal and, thereby, introduces a delay into the input signal. When the selection signal sel rises from a low potential level to a high potential level, the time delay between the input signal and the output signal at the output terminal CK_o determines the delay cell's delay resolution, which could be altered by adjusting the size of the capacitor C. When the size of the capacitor C is at the smallest possible value allowed by the manufacturing process, the time delay between the input and output signal, therefore, would be the delay cell's finest delay resolution. In other words, the conventional delay cell's delay resolution is inherently limited by the smallest capacitor size achievable by the manufacturing process. Even though the delay resolution could be improved by reducing the signal's rise/fall time through increasing the sizes and, thereby, the driving capabilities, of the inverters M1 and M2, this improvement comes with a price-the increased power consumption of the delay cell. In addition, no matter whether the selections signal sel is at low or high potential level, the components on the two signal paths are constantly driven the input signal, causing significant ineffective power consumption.

FIG. 1b is a schematic diagram showing another conventional delay cell. The delay cell illustrated is very similar to what is depicted in FIG. 1a, except that the multiplexer formed by the logic gates is replaced by a single multiplexer MS, the transistor-based capacitor C is replaced by an inverter M3, and inverters M1 and M2 by buffers M1′ and M2′. The operation principles of the two delay cells are also very similar. When the size of the inverter M3 is at the smallest possible value allowed by the manufacturing process, the time delay between the input and output signal is the delay cell's finest delay resolution. Again, the delay resolution could be improved by increasing the sizes and, thereby, the driving capabilities, of the buffers M1′ and M2′ at the price of the increased power consumption of the delay cell. In addition, the delay cell also suffers significant ineffective power consumption from the input signal's constant driving the components on the two signal paths.

FIG. 1c is a schematic diagram showing another conventional delay cell. As illustrated, the delay cell has a single signal path (marked as “path” in the diagram), along with an inverter M, a MOS switch S, and capacitors C1 and C2 formed by NMOS and PMOS transistors respectively. When the sizes of the capacitors C1 and C2 are at the smallest possible values allowed by the manufacturing process, the time delay between the input and output signal is the delay cell's finest delay resolution. Again, the delay resolution could be improved by increasing the sizes of the inverter M and MOS switch S at the price of the increased power consumption. In addition, the delay cell also suffers significant ineffective power consumption from the input signal's constant driving the components on the signal path.

### SUMMARY OF THE INVENTION

The major objective of the present invention is to provide a delay cell circuit that can obviate the following disadvantages of the conventional delay cells. First, the delay resolution of the conventional delay cells is inherently limited by the smallest size achievable by the manufacturing process. Secondly, when the conventional delay cells increase the driving capabilities of their logic gates so as to enhance the delay resolution, their power consumption is increased as well. Thirdly, the conventional delay cells suffer significant ineffective power consumption from the input signal's constant driving the components of the signal paths. Furthermore, for the conventional delay cells using a single capacitor, a shift in the capacitance of the capacitor resulted from the imprecise control of manufacturing process would be directly reflected in the delay cell's resolution which might affect the operation of the entire system.

The main characteristic of the delay cell of the present invention is the provision of two signal paths, each of which has a capacitor connected to the ground realized by a transistor whose size could be tuned during the manufacturing process. The delay resolution of the delay cell is determined by the capacitance difference between the two capacitors, instead of the capacitance of either one of the capacitors. By having one of the capacitors manufactured to the smallest possible size and having the other one manufactured to a slightly larger size, the delay cell is no longer bounded by the manufacturing process, but can have a very fine delay resolution. In addition, as any flaws in the manufacturing process would affect both capacitors, their capacitance difference and, thereby, the delay resolution of the delay cell would remain within a specific range, keeping the system's operation intact.

As the delay resolution of the delay cells of the present invention could be far greater than the conventional delay cells, there is basically no need to increase the sizes of the logical gates so as to improve the delay resolution. However, if still required, this approach could still be applied to the delay cells of the present invention.

The other major characteristic of the present invention is that a de-multiplexer is used to replace the path-selection logic gates in the conventional delay cells which contributes to the constant driving of the signal paths from the input signal. The de-multiplexer of the present invention, at any one time, always keeps one path at a steady state while allowing only the other path to be driven by the input signal, and therefore the ineffective power consumption is reduced dramatically.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIG. 1a is a schematic diagram showing a conventional delay cell.

FIG. 1b is a schematic diagram showing another conventional delay cell.

FIG. 1c is a schematic diagram showing another conventional delay cell.

FIG. 2a is a schematic diagram showing the delay cell according to a first embodiment of the present invention.

FIG. 2b is a schematic diagram showing the delay cell according to a second embodiment of the present invention.

FIG. 3a is a schematic diagram showing the delay cell according to a third embodiment of the present invention.

FIG. 3b is a schematic diagram showing the delay cell according to a fourth embodiment of the present invention.

### DETAILED DESCRIPTION OF THE PREFERRED EMBODIMENTS

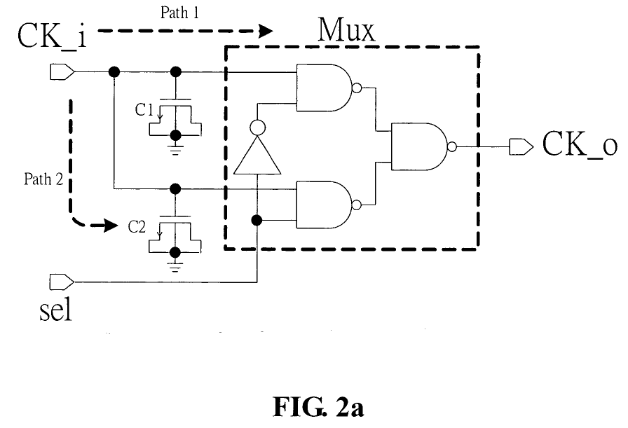

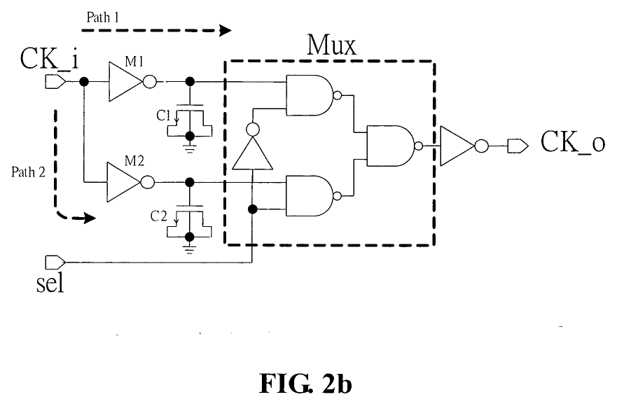

FIG. 2a is a schematic diagram showing the delay cell according to a first embodiment of the present invention. As illustrated, the present embodiment provides two signal paths, marked as “path 1” and “path 2” in the drawing. Path 1 and path 2 have capacitors C1 and C2 connected to the ground, which are realized by MOS transistors whose sizes could be tuned during the manufacturing process respectively. The present embodiment also contains an inverter and three NAND gates, jointly forming a multiplexer Mux, marked by the dashed line in the drawing.

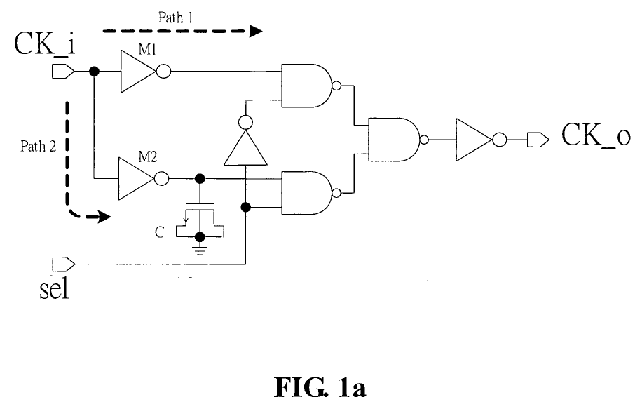

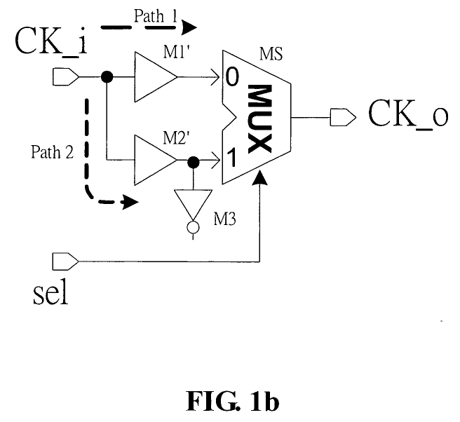

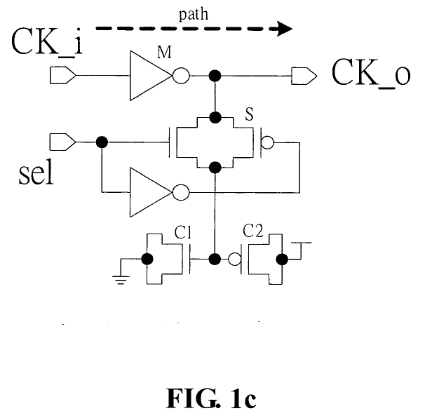

The present embodiment has a structure very similar to that of FIG. 1a and its operation principle is omitted here. The major characteristic of the present embodiment lies in that its delay resolution is determined by the capacitance difference between the two capacitors C1 and C2 (therefore, it is named “differential-type delay cell). By having the one of the capacitors, say C1, manufactured to the smallest possible size and having the other one (i.e., C2) manufactured to a slightly larger size, the delay resolution of the present embodiment is no longer constrained by the manufacturing process, but can have a very fine delay resolution. In addition, as any flaws in the manufacturing process would affect both capacitors C1 and C2 and their capacitances would be shifted together for compatible amounts, their capacitance difference and, thereby, the delay resolution of the present embodiment would remain within a specific range, keeping the system's operation intact.

As described, the present embodiment could achieve a delay resolution far greater than that of any conventional delay cells. Basically there is no need to configure additional logic gates for stronger driving capability. However, if still required, such possibility is not ruled out by the present embodiment. FIG. 2b is a schematic diagram showing the delay cell according to a second embodiment of the present invention. As shown, the present embodiment is almost identical to the first embodiment of FIG. 2a, except that two inverters M1 and M2 are installed on path 1 and path 2 respectively. With the addition of inverters M1 and M2, the present embodiment would have a less strength requirement to the input signal, in addition to the further improvement to the delay resolution by reducing the signal's rise/fall time. In order to ensure the output signal at CK_o has the same polarity as the input signal at CK_i, an inverter (not numbered) is configured between the output of the multiplexer Mux and the output terminal CK_o. Please note that inverter is not the only choice for increasing the driving capability; other suitable types of logic gates could be used as well. However, if inverters are used, there should have an even number of inverters arranged along the signal paths between CK_i and CK_o so as to maintain the signal polarity.

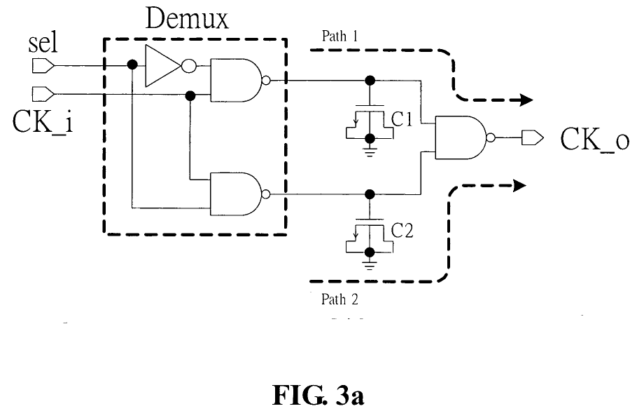

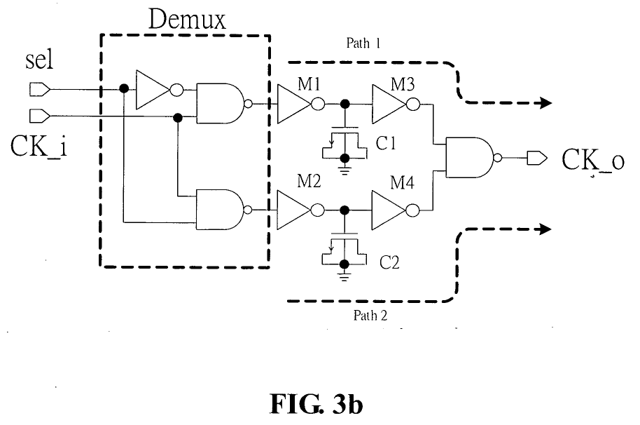

Please also note that the two signal paths, path 1 and path 2, are still under the constant driving of the input signal. To resolve the ineffective power consumption problem, as shown in FIG. 3, the multiplexer before the output terminal CK_o is replaced by de-multiplexer Demux, marked by the dashed line in the drawing, arranged after the input terminal CK_i. The de-multiplexer Demux is composed by an inverter and two NAND gates and, under the control of the selection signal sel, only one of the signals would be activated by the input signal while the other one would remain in a steady state at any point of time. Compared to the previous embodiment, the present embodiment not only preserves the benefit of breaking the constraint of the manufacturing process on the delay resolution, but also effectively reduces the ineffective power consumption.

Again, there is no need to configure additional logic gates for stronger driving capability. However, if required, as shown in FIG. 3b, inverters M1 and M3, and inverters M2 and M4 are configured on path 1 and path 2 respectively. Similar to the previous embodiments, inverters are not the only choice for increasing the driving capability; other suitable types of logic gates could be used as well. However, if inverters are used, there should have an even number of inverters arranged along the signal paths between CK_i and CK_o so as to maintain the signal polarity.

The idea of using de-multiplexer to reduce ineffective power consumption could also be applied to conventional delay cells that have only one capacitor. For example, some embodiments have structures similar to the one shown in either FIG. 3a or FIG. 3b but with only one of the capacitors C1 and C2 present. As can be imagined, these embodiments could have their ineffective power consumption reduced but their delay resolutions are still under the constraint of the manufacturing process.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A differential-type delay cell having an input terminal and an output terminal, said delay cell under the control of a selection signal producing an output signal at said output terminal having a time delay relative to an input signal at said input terminal, said delay cell comprising:
a multiplexer, said multiplexer having a first input end, a second input end, and an output end, said output end is connected to said output terminal of said delay cell, said multiplexer connected to said selection signal and, under the control of said selection signal, said multiplexer delivering a signal either at said first input end or said second input end to said output end;
a first path, said first path having one end connected to said input terminal of said delay cell, and the other end connected to said first input end of said multiplexer, a first capacitor is connected between said first path and the ground; and
a second path, said second path having one end connected to said input terminal of said delay cell, and the other end connected to said second input end of said multiplexer, a second capacitor is connected between said second path and the ground;
wherein said time delay is determined by the capacitance difference of said first capacitor and said second capacitor.

2. The delay cell as claimed in claim 1, wherein said first capacitor and said second capacitor are formed using MOS transistors.

3. The delay cell as claimed in claim 1, wherein said multiplexer further comprises a first, a second, and a third dual-input NAND gate and a single-input inverter, said first input end and said second input end of said multiplexer are connected to an input end of said first NAND gate and said second NAND gate respectively, said selection signal is connected to the other input end of said second NAND gate, said selection signal is connected to an input end of said inverter whose output end is connected to the other input end of said first NAND gate, the output ends of said first and said second NAND gates are connected to the two input ends of said third NAND gate respectively, the output end of said third NAND is connected to said output end of said multiplexer.

4. The delay cell as claimed in claim 1, wherein at least a logic gate is configured in serial along said first path at either side of said first capacitor so as to increase signal strength on said first path, and at least a logic gate is configured in serial along said second path at either side of said second capacitor so as to increase signal strength on said second path.

5. The delay cell as claimed in claim 1, wherein a plurality of even-numbered inverters are configured along said first path in serial on at least a side of said first capacitor so as to increase signal strength of said first path, and a plurality of even-numbered inverters are configured along said second path in serial on at least a side of said second capacitor so as to increase signal strength of said second path.

6. The delay cell as claimed in claim 1, wherein odd-numbered inverters are configured along said first path in serial on at least a side of said first capacitor so as to increase signal strength of said first path, odd-numbered inverters are configured along said second path in serial on at least a side of said second capacitor so as to increase signal strength of said second path, and odd-numbered inverters are configured in serial between said output end of said multiplexer and said output terminal of said delay cell so as to maintain consistent polarity between said input signal and said output signal of said delay cell.

7. A differential-type delay cell having an input terminal and an output terminal, said delay cell under the control of a selection signal producing an output signal at said output terminal having a time delay relative to an input signal at said input terminal, said delay cell comprising:
a de-multiplexer, said de-multiplexer having a first output end, a second output end, a first input end, and a second input end, said first input end is connected to selection signal, said second input end is connected to said input terminal of said delay cell, said de-multiplexer, under the control of said selection signal, processing and delivering a signal at said second input end to either said first output end or said second output end;
a first path, said first path having one end connected to said first output end of said de-multiplexer;
a second path, said second path having one end connected to said second output end of said de-multiplexer; and
a dual-input, single-output logic gate, said logic gate having a first input end, a second input end, and an output end, said first input end connected to said first path, said second input end connected to said second path, said output end is connected to said output terminal of said delay cell;
wherein a capacitor is connected between one of said first path and said second, and the ground, said time delay is determined by the capacitance of said capacitor, and said de-multiplexer ensures that only one of said first path and said second path is activated by said input signal of said delay cell.

8. The delay cell as claimed in claim 7, wherein said capacitor is formed using MOS transistor.

9. The delay cell as claimed in claim 7, wherein said de-multiplexer further comprises a first and a second dual-input NAND gates and a single-input inverter, said first input end of said de-multiplexer is connected to an input of said inverter whose output is connected an input end of said first NAND gate, said first input end of said de-multiplexer is connected to an input end of said second NAND gate, said second input end of said de-multiplexer is connected simultaneously to the other input end of said first NAND gate and the other input end of said second NAND gate, said output end of said first NAND gate is connected to said first output end of said de-multiplexer, and said output end of said second NAND gate is connected to said second output end of said de-multiplexer.

10. The delay cell as claimed in claim 7, wherein at least a logic gate is configured in serial along a path where said capacitor is connected on at least a side of said capacitor so as to increase signal strength of said path.

11. The delay cell as claimed in claim 7, wherein a plurality of even-numbered logic gates are configured in serial along a signal path where said capacitor is connected on at least a side of said capacitor so as to increase signal strength of said path.

12. The delay cell as claimed in claim 7, wherein said logic gate is a NAND gate.

13. A differential-type delay cell having an input terminal and an output terminal, said delay cell under the control of a selection signal producing an output signal at said output terminal having a time delay relative to an input signal at said input terminal, said delay cell comprising:
a de-multiplexer, said de-multiplexer having a first output end, a second output end, a first input end, and a second input end, said first input end is connected to selection signal, said second input end is connected to said input terminal of said delay cell, said de-multiplexer, under the control of said selection signal, processing and delivering a signal at said second input end to either said first output end or said second output end;
a dual-input, single-output logic gate, said logic gate having a first input end, a second input end, and an output end, said output end connected to said output terminal of said delay cell;
a first path, said first path having one end connected to said first output end of said de-multiplexer, and the other end connected to said first input end of said logic gate, a first capacitor is connected between said first path and the ground; and
a second path, said second path having one end connected to said second output end of said de-multiplexer, and the other end connected to said second input end of said logic gate, a second capacitor is connected between said second path and the ground;
wherein said time delay is determined by the capacitance difference of said first capacitor and said second capacitor, and said de-multiplexer ensures that only one of said first path and said second path is activated by said input signal of said delay cell.

14. The delay cell as claimed in claim 13, wherein said first capacitor and said second capacitor are formed using MOS transistors.

15. The delay cell as claimed in claim 13, wherein said de-multiplexer further comprises a first and a second dual-input NAND gates and a single-input inverter, said first input end of said de-multiplexer is connected to an input of said inverter whose output is connected an input end of said first NAND gate, said first input end of said de-multiplexer is connected to an input end of said second NAND gate, said second input end of said de-multiplexer is connected simultaneously to the other input end of said first NAND gate and the other input end of said second NAND gate, said output end of said first NAND gate is connected to said first output end of said de-multiplexer, and said output end of said second NAND gate is connected to said second output end of said de-multiplexer.

16. The delay cell as claimed in claim 13, wherein at least a logic gate is configured in serial along said first path at either side of said first capacitor so as to increase signal strength on said first path, and at least a logic gate is configured in serial along said second path at either side of said second capacitor so as to increase signal strength on said second path.

17. The delay cell as claimed in claim 13, wherein a plurality of even-numbered inverters are configured along said first path in serial on at least a side of said first capacitor so as to increase signal strength of said first path, and a plurality of even-numbered inverters are configured along said second path in serial on at least a side of said second capacitor so as to increase signal strength of said second path.

18. The delay cell as claimed in claim 13, wherein said logic gate is a NAND gate.
